(19) United States
(12) Patent Application Publication
(10) Pub. No.: US 2024/0102526 A1
(43) Pub. Date: Mar. 28, 2024

(54) PRELOAD DEVICE AND DRIVE DEVICE COMPRISING A PRELOAD DEVICE

(71) Applicant: PHYSIK INSTRUMENTE (PI) GMBH & CO. KG, Karlsruhe (DE)

(72) Inventors: Daniela TROLL, Bietigheim (DE); Harry MARTH, Waldbronn (DE)

(21) Appl. No.: 18/275,974

(22) PCT Filed: Jan. 23, 2022
(86) PCT No.: PCT/EP2022/051412

§ 371 Date: Aug. 4, 2023

(30) Foreign Application Priority Data
Feb. 5, 2021 (DE) 10 2021 102 793.4

(51) Int. Cl. F16F 1/02; H10N 30/88

(52) U.S. Cl. CPC F16F 1/025; H10N 30/886

(57) ABSTRACT

A preloading device (10, 100, 300) with a first end part (11, 111), with a second end part (12, 112) and with at least one spring device (F, F1, F2), which connects a second end part (12, 112) to the first end part (11, 111) along a spring device reference axis (RA, RA1, RA2), wherein the at least one spring device (F, F1, F2) is formed of at least one meander section (M1), each of which extends along the spring device reference axis (RA, RA1, RA2), and a drive device (1) with a preloading device (10, 100, 300).

### CLAIM TO PRIORITY

This application claims priority to and the benefit of the following pending application PCT/EP2022/051412 having an International filing date 23 Jan. 2022 (23.01.2022) which claims priority to Priority Application No. DE 10 2021 102 793.4 having a priority date of 5, Feb. 2021 (05.02.2021)

### FIELD OF INVENTION

The invention relates to a preloading device and a drive device with a preloading device.

### BACKGROUND

From the EP 1 267 478 B1 A preloading device is known from U.S. Pat. No. 10,389,276 B2, U.S. Pat. No. 5,543,670 and WO 2015 113998 A1.

An object of the invention is to provide a preloading device or drive device designed as an alternative to the known preloading device and drive device, which is advantageous in terms of accuracy as well as in terms of manufacture and assembly, and with which a high preloading force can be achieved in particular.

This object is solved with the features of the independent claims. Further embodiments are specified in the subclaims which refer back to the same.

### SUMMARY

According to the invention, a preloading device is provided with a first end part, with a second end part and with at least one spring device, which connects the first end part and the second end part along a spring device reference axis RA. At least one spring device of the preloading device or several or each of the at least one spring device is formed from at least one meander section or loop-shaped section, wherein in these variants at least one meander section or loop-shaped section extends along or parallel to the spring device reference axis. In a sequence of several meander sections or loop-shaped sections, the meander sections are lined up in the spring device reference axis RA, wherein meander sections or loop-shaped sections which are disposed closest or adjacent to one another may be connected directly to one another or may be connected to one another via an intermediate part.

In each of the embodiments according to the invention with otherwise all the features of the preloading device or the drive device described herein, a meander section or loop-shaped section comprises, in particular, two transversal sections, whose distance from each other, when viewed from a reference line or the spring device reference axis RA of the respective spring device, increases at least in a section and which form a distance enlargement section, wherein the two transversal sections are connected with each other in a bridging or connecting section, which is connected to the distance enlargement section and thus is disposed at a greater distance from the reference line or the spring device reference axis. A meander section or loop-shaped section thus extends in particular on the same side of the reference line or the spring device reference axis RA.

In all embodiments according to the invention, it can be provided in particular that between transversal sections of the same meander sections and/or between transversal sections of different adjacent meander sections, at least in a part of the range of movement or in the entire range of movement of the respective spring device, a free movement space in the direction of the reference line or the spring device reference axis exists. As a result, the respective spring device can contract or expand in the direction of the reference line or the spring device reference axis in case that corresponding external forces are applied to the respective end parts between which the respective spring device extends.

In each embodiment of the invention, which comprises a spring device or several spring devices in each case between two end pieces, each with multiple meander sections or loop-shaped sections, it can be provided that at least two meander sections, which follow one another along the reference line or spring device reference axis, extend from the reference line or spring device reference axis in mutually opposite directions or are located on mutually opposite sides with respect to the reference line or spring device reference axis.

In the embodiments of the preloading device according to the invention with a meander section or several meander sections in combination with all other features of the preloading device or the drive device described herein, it is provided that at least one meander section in its course comprises a meander center line and is formed from the following sections (A1), (A2), (A3):
(A1) a first transversal section, which runs from a first transversal section initial point to a first transversal section final point, wherein the first transversal section initial point is identical to the meander section initial point or the first transversal section initial point is disposed by means of an initial section in a distance from the meander section initial point, wherein the course of the meander center line in the first transverse section is defined in such a way that, when a line point moves on the meander center line from the first transversal section initial point to the first transverse section final point, a point resulting from the perpendicular projection of the moved line point onto the spring device reference axis RA approaches the first end part,
(A2) a bridging section, which extends from the first transversal section final point in direction to the second end part,
(A3) a second transversal section, which runs from the bridging section final point to a second transversal section final point, which is identical to the meander section final point or is located at a distance from the meander section final point by means of an end section, wherein the course of the meander center line in the second transversal section is defined in such a way that when a line point moves on the meander center line from the bridging section final point to the second transversal section final point, a point which results from the perpendicular projection of the moved line point onto the spring device reference axis RA, approximates the first end part.

With regard to the first transversal section according to definition (A1), the line point of the meander center line which is moved on the meander center line is a fictitious point for defining the course of the meander center line in the first transversal section. In particular, the course of the meander center line in the first transversal section can be defined in such a way that when a fictitious line point moves on the meander center line from the first transversal section initial point to the first transversal section final point, the projection point that results from the projection of the line point moved on the meander center line perpendicular to the spring device reference axis RA is moved in a direction going from the second end part to the first end part and simultaneously along the spring device reference axis RA.

With regard to the first transversal section according to definition (A2), the line point of the meander center line which is moved on the meander center line is a fictitious point for defining the course of the meander center line in the second transversal section. In particular, the course of the meander center line in the second transversal section can be defined in such a way that when a fictitious line point moves on the meander center line from the bridging section end point to the second transversal section final point, the projection point that results from the projection of the line point moved on the meander center line perpendicular to the spring device reference axis RA is moved in a direction going from the second end part to the first end part and simultaneously along the spring device reference axis RA.

A linear preloading is achieved by the preloading device according to the invention.

Due to the geometry or design of the at least one spring device, strong preloading, i.e., the generation of relatively large pretensioning forces of a component located between the end parts and in particular of an actuator, preferably a piezoelectric actuator, can be achieved. The component located between the end parts can be mounted directly on the end parts or via at least an intermediate component.

The preloading device according to the invention has the advantage that the mechanical stresses occurring in the at least one spring device or the mechanical stress in the material of the at least one spring device within the flexible area or the deformation area are relatively small in relation to the achievable elongation or the achievable preloading force, in particular since relatively large resulting notch radii can be realized with the preloading device according to the invention, so that a reduction or limitation of stress peaks in the at least one spring device can be achieved. These effects can also be flexibly adjusted through the targeted shape of the spring device.

In each embodiment of the preloading device according to the invention with all the other features otherwise described herein and optionally alternative features, it can be provided that the spring device reference axis RA is a center line of the spring device or runs parallel to a center line of the spring device.

In each embodiment of the preloading device according to the invention with all other features otherwise described herein and optionally alternative features, it can be provided that the section of the meander center line of at least one meander section has one of the following forms between the first transversal section final point and the bridging section final point:
(C1) a rectilinear course;
(C2) an arcuate curve with a uniform curvature, which is concavely curved when viewed from the spring device reference axis RA.

In each embodiment of the preloading device according to the invention with all other features otherwise described herein and, where appropriate, optionally alternative features, it can be provided that at least one meander section is shaped in such a way that the section of the meander center line between the first transverse section initial point and the transverse section final point is a circle segment line, wherein the center of the circle segment is defined by the intersection of the following two lines:
(R1) the perpendicular to the tangent to the meander center line in the first transversal section initial point, wherein the meander centerline is disposed in the first transversal section,
(R2) the perpendicular to the tangent to the meander center line in the second transversal section in the second meander final point, wherein the meander centerline is disposed in the second transversal section,
wherein the opening angle φ, which extends between the two perpendiculars, is greater than 180 degrees.

In addition, it can be provided that the opening angle (φ), which extends between the two perpendiculars (SP1, SP6), is less than 330 degrees.

In this regard, it can be specifically provided that the opening angle between the two perpendiculars (SP1, SP6) over the course of the first meander section (M1) is greater than 180.5 degrees. In this regard, it can be provided that the opening angle between the two perpendiculars (SP1, SP6) over the course of the first meander section (M1) is less than 350 degrees, and specifically less than 330 degrees.

In each embodiment of the preloading device according to the invention with all the other features otherwise described herein and optionally alternative features, it can be provided that the spring device comprises two or more than two meandering sections. At least one meander section comprises the sections (A1), (A2), (A3), wherein the bridging sections of meander sections, which are located one behind the other along the spring device reference axis RA, are located periodically and alternating on different sides of the spring device reference axis RA. In each embodiment of the preloading device according to the invention with at least two meander sections, it can be provided in particular that the bridging sections of meander sections, which are located one behind the other along the spring device reference axis RA, are located periodically alternately on different sides of the spring device reference axis RA.

In particular in these embodiments of the preloading device according to the invention, it can be provided that the spring device reference axis RA is a center line of the spring device.

In particular in these embodiments of the preloading device according to the invention with all other features otherwise described herein and, if applicable, optionally alternative features it can be provided that the spring device comprises at least one first meander section and at least one further meander section, which are located one behind the other along the spring device reference axis RA and in this case may follow one another or can be connected to one another via an intermediate section or an intermediate component. In these embodiments of the preloading device according to the invention, it can be provided with all the other features otherwise described herein,
that the first meander section is formed from the sections (A1), (A2), (A3) mentioned herein,
that the further meander section is also formed from the sections (A1), (A2), (A3) mentioned herein,
wherein the further meander section with the first transversal section according to the definition (A1) follows the second transversal section of the first meander section,
wherein the further meander section comprises a bridging section according to the definition (A2), which follows the first transversal section of the further meander section,
wherein the further meander section (M2) comprises a second transversal section according to the definition (A3), which follows the bridging section of the further meander section,
wherein the bridging section of the first meander portion and the bridging section of the further meander portion are located on mutually different sides of the spring device reference axis RA.

In particular, the further meander section (M2) can comprise a bridging section according to the definition (A2) made herein, which adjoins the first transversal section of the further meander section (M2). In particular, the further meander section (M2) comprises a second transversal section according to the definition (A3) made herein, which adjoins the bridging section of the further meander section. In particular, the second transversal section of the first meander section and the second transversal section of the further meander section extend from their respective bridging section final point in the direction to their respective second transversal section final point or in relation to the spring device reference axis RA in opposite directions in relation to each other.

In each embodiment of the preloading device according to the invention with all the other features otherwise described herein, it can be provided that the thickness of at least one meander section of the at least one meander section, in an area between the first transverse section initial point and the second meander final point, increases continuously along the course of the meander center line and decreases again after reaching a maximum thickness, wherein the maximum thickness occurs in a middle area of the bridging section. It can be provided in particular that the thickness is formed transversely or vertically to the plane or a central plane in which the radii of curvature lie on the meander center line in the bridging section.

In each embodiment of the preloading device according to the invention with a meander section and with one or more of the other features of the preloading device otherwise described herein, it can be provided that the meander section of the preloading device contains the initial section or the end section (90) or both the initial section as well as the end section.

In each embodiment of the preloading device according to the invention with a plurality of meander sections and with one or more of the other features of the preloading device otherwise described herein, it can be provided that at least one of the meander sections of the preloading device comprises the initial section or the end section or both the initial section as well as the end section.

In each embodiment of the preloading device according to the invention with at least one initial section, it can be provided that the meandering center line of at least one initial section runs in a straight line.

In each embodiment of the preloading device according to the invention with at least one end section, it can be provided that the meander center line of at least one end sections runs in a straight line.

In each embodiment of the preloading device according to the invention with at least two adjacent and adjoining meander sections and with one or more of the other features of the preloading device otherwise described herein, it can be provided that one of the meander sections comprises an end section and the adjacent meander section has an initial section, wherein the initial section is directly connected to the end section. In this case, it can be provided in particular that the initial section, which directly adjoins the end section, is arranged point-symmetrically to the end section.

In these embodiments with at least two consecutive meander sections, provision can be made that the spring device reference axis RA runs through the common point at which an end section and an initial section which directly adjoins the same meet each other.

In each embodiment of the preloading device according to the invention with one or more of the other features of the preloading device otherwise described herein, it can be provided that the preloading device comprises a first spring device, which connects the first end part and the second end part along a first spring device reference axis RA1, and a second spring device, which connects the first end part and the second end part along a second spring device reference axis RA2, wherein each spring device is formed of at least a meander section with a meander center line and is formed of sections (A1), (A2), (A3).

According to a further aspect of the invention, the preloading device according to the invention can comprise a first end part, a second end part and at least one spring device which connects the first end part and the second end part along a spring device reference axis.

In this case, embodiments of the preloading device according to the invention with otherwise all other features according to the invention can comprise at least one spring device (F1, F2) with at least one meander section (M1, M2) each with two transversal sections (50, 70; 150, 170; 250, 270), which, viewed from a reference line or the spring device reference axis (RA, RA1, RA2) of the respective spring device, increase their distance from one another in a section and which are connected together in a bridging section at a greater distance from the reference line or the spring device reference axis (RA, RA1),
wherein the first end part (11, 111) or the second end part (12, 112) or both the first end part (11, 111) and the second end part (12, 112) comprise a decoupling device (30, 130) for elimination the effect of transverse forces directed transversely to the spring device reference axis (RA, RA1, RA2),
wherein the decoupling device (30, 130) forms one of the following feature groups (U), (V) or both of the following feature groups (U), (V):
(U) the decoupling device comprises a first rotary bearing (131) with a first axis of rotation and a second rotary bearing (132) with a second axis of rotation, wherein the first axis of rotation and the second axis of rotation run transversely to one another,
(V) the decoupling device (30, 130) comprises at least one flexure hinge or structural hinge.

Furthermore, embodiments of the preloading device according to the invention with otherwise all other features according to the invention can comprise at least one spring device (F1, F2) each with at least a meander section (M1, M2), which in particular realizes an overall elongated shape and the shape of a meander loop with
(B1) a first transversal section,
(B2) a bridging section,
(B3) a second transversal section,
wherein the bridging section connects the first transversal section to the second transversal section. A vertical plane VE can be defined in such a way that the respective spring device reference axis is located in this plane and intersects the bridging section at least in a section.

In this case provision can be made
that the first transversal section comprises a first outer surface section with at least one first surface section, which is oriented towards the first end part at least in a section, and a second surface section, which is oriented opposite to the first surface section, wherein the adjacent angle α between the contour line, which results from the intersection of the first surface section with the vertical plane VE, and the respective spring device reference axis, which opens on the end part of the first end part, is at least in a section less than 90 degrees,
that the second transversal section comprises a second outer surface section with at least one first surface section, which, at least in a section, is oriented towards the second end part and a second surface section, which is oriented opposite to the first surface section, wherein adjacent angle γ between the contour line, which results from the intersection of the first surface section with the vertical plane (VE), and the respective spring device reference axis, which opens on the side of the second end part, at least in a section amounts to less than 90 degrees.

This embodiment of the preloading device according to the invention can be realized with all the other features otherwise described herein and optionally alternative features.

In these embodiments of the preloading device provision can be made
that the spring device comprises at least two meandering sections, each of which comprises sections (B1), (B2), (B3),
that a second transversal section of a first meander section is followed by a first transversal section of a second meander section,
that the bridging sections of meander sections, which are located one behind the other along the spring device reference axis RA, RA1, RA2, are located periodically alternately on different RA, RA1, RA2.

In each embodiment of the preloading device according to the invention with one or more of the other features of the preloading device otherwise described herein, it can be provided that the preloading device comprises a first spring device and a second spring device each with at least two meander sections, wherein each of the meander sections of each of the spring devices is formed with the sections (A1), (A2), (A3), wherein the bridging sections of meander sections of the same spring device, which are located one behind the other along the respective spring device reference axis, are located periodically alternating on different sides of the respective spring device reference axis.

In each embodiment of the preloading device according to the invention with a first spring device and a second spring device, it can be provided that the first spring device and the second spring device are arranged axially symmetrical to one another with respect to a spring device symmetry axis which runs parallel to the spring device reference axis RA. In these embodiments of the preloading device according to the invention, it can be provided in particular that the first spring device reference axis RA1 of the first spring device and the second spring device reference axis RA1 of the second spring device are arranged axially symmetrically with respect to a spring device symmetry axis. In these embodiments of the preloading device according to the invention, it can also be provided that the first spring device reference axis RA1 of the first spring device and the second spring device reference axis RA1 of the second spring device run parallel to one another. In these embodiments of the preloading device according to the invention, it can also be provided that the outer contour of the first spring device and the outer contour of the second spring device are designed to be essentially identical to one another.

In each embodiment of the preloading device according to the invention with one or more of the other features of the preloading device otherwise described herein, it can be provided that the first end part or the second end part or both the first end part and the second end part comprises a decoupling device for elimination of the effect of lateral forces directed transversely to the spring device reference axis RA. The transverse forces can in particular be transverse forces which act on the first end part or the second end part or both the first end part and the second end part. In particular, the decoupling device can be located between two sections or sections of the respective end parts in order to eliminate lateral forces between these partial sections or partial pieces. The sections or parts are arranged one behind the other along the respective spring device reference axis. It is also conceivable, however, that the partial sections or partial pieces are arranged so that they overlap one another, i.e., on top of one another or one above the other, in order to implement a universal joint arrangement.

The at least one decoupling device ensures that no or only relatively small transverse forces, i.e., forces transverse to the spring device reference axis RA, are transferred from the end parts to the at least one spring device.

In each embodiment of the preloading device according to the invention, with at least one decoupling device, it can be provided that the decoupling device comprises at least one pivot bearing or one tilting bearing. In the case of the respective pivot bearing, the partial sections or partial pieces are rotatably connected by the decoupling device to one another. In the case of the respective pivot bearing, partial sections or partial pieces, which are connected by the decoupling device, are connected such that they can be tilted or pivoted relative to one another.

In each embodiment of the preloading device according to the invention with at least one decoupling device, it can be provided that the decoupling device comprises a first pivot bearing or tilting bearing or swivel bearing with a first pivot axis or tilting axis or swivel axis and a second pivot bearing or tilting bearing or swivel bearing with a second pivot axis or tilting axis or swivel axis, wherein the first pivot or first tilting or first swivel axis and the second pivot axis or second tilting axis or second swivel axis run transversely to one another.

In each embodiment of the preloading device according to the invention with at least one decoupling device with at least one pivot bearing, it can be provided that the pivot bearing is realized as a flexure pivot bearing or a structural pivot bearing or comprises a flexure pivot bearing or a structural pivot bearing.

In each embodiment of the preloading device according to the invention with at least one decoupling device, it can be provided that the decoupling device comprises a layer of pseudoplastic or shear-thinning material in relation to the spring device reference axis RA.

In general, it can be provided that each embodiment of a spring device described herein is manufactured by wire eroding.

According to a further aspect of the invention a drive device with an embodiment of the preloading device according to the invention and with an actuator, which is arranged between the first end part and the second end part and which expands or contracts along the spring device reference axis RA when actuated, is provided.

The actuator can in particular be a piezo actuator, i.e., an actuator made of piezoelectric material. In general, actuators made from a different electromechanical material are also conceivable.

In embodiments of the drive device with at least one end part which comprises a decoupling device, it is achieved that the end parts transmit no or only relatively small transverse forces, i.e., forces which are directed transversal to the spring device reference axis RA, to the actuator. This prevents the occurrence of unfavorable bending loads on the actuator due to transverse forces in case that the drive element is installed between the end parts and in case that the end parts are mounted to the application environment, e.g., with a first application component and a second application component. In this case, the first application component and the second application component can be coupled by means of an application kinematics such that they can move with respect to one another. The decoupling device also ensures a reduction or avoidance of transverse forces on the actuator, which can result from the operation of the drive device.

The term “along” means in connection with a directional statement mentioned herein, which can also relate in particular to the course of a contour line or of a surface or a direction of a component or of a structural component such as an axis or a shaft or a central axis thereof, in relation to a reference direction or a reference axis, that a section of the course or the tangent to a respective contour line or a respective surface or the direction in an explicitly or implicitly specified viewing direction locally or in a section deviates with an angle of maximum 45 degrees and in particular of maximum 30 degrees from the respective reference direction or reference axis to which the respective direction information is based.

The term “transverse” means in connection with a directional statement mentioned herein, which can also relate in particular to the course of a contour line or of a surface or a direction of a component or of a structural component such as an axis or a shaft or a central axis thereof, in relation to a reference direction or a reference axis, that a section of the course or the tangent to a respective contour line or a respective surface or the direction in an explicitly or implicitly specified viewing direction locally or in a section deviates with an angle, which is between 45 degrees and 135 degrees, and preferably with an angle which is between 67 degrees and 113 degrees, from the respective reference direction or reference axis to which the respective directional information is based.

The term “distance” in particular between two surfaces is understood here to mean the shortest distance in particular.

More specifically, a “distance” in particular between two objects or two surfaces or reference points, can be understood herein to mean in particular the shortest distance or the shortest distance between the two objects or surfaces or reference points, wherein the shortest distance or the shortest distance being non-zero in absolute value, unless explicitly stated otherwise in this regard.

A “center line” or a “longitudinal direction” or “reference axis” or another reference line, such as in particular a central axis or a line running in the middle, of at least one structural component or part, which can be a meander section in particular, can be defined herein in such a way that the same results in particular as a connecting line of the centroids of the respective smallest cross-sectional areas of the respective structural component at each point along a determined or specified reference line or a course between two determined or specified ends of the structural component or a part and in particular of a meander section. However, a “center line” of a reference line herein may also run according to any other definition known in the art. In case that the reference line can be curved or at least partially curved, a reference direction at a point on the reference line can generally be understood as a local longitudinal direction and can in particular have the direction of the tangent to this point.

Here, however, a reference axis can also be understood as a linearly defined line or axis of a curved reference line and, for example, of a center line, wherein for determination of a rectilinear reference axis a line can be used whose arrangement relative to the curved line and, for example, center line in the sum results in the smallest area of deviation between these lines or the smallest area of deviation. The same applies if a straight reference line is to be derived from a curved line herein.

The term “substantially” in relation to a characteristic or value is understood herein in particular to mean that the characteristic contains a deviation of 20% and especially 10% from the characteristic or its geometric property or value.

“Orientation” in relation to a region and in particular a surface is understood here to mean the normal to the respective surface. In the case that the surface in question is not a straight but, for example, a curved surface, the normal to a straight surface of the same characteristic can be used to determine the surface normal, for whose position relative to the curved surface is given in the sum the smallest deviation.

An “extension” of a surface section is understood to mean a direction of a planar surface section that runs along the referenced surface section and has such an arrangement in relation to it that the sum of the deviation amounts between both surface sections is minimal. With regard to a length of the extension of a surface section, a length of a fictitious surface section of the same size in a direction to be defined is understood here, which has an arrangement relative to the referenced surface section in which the sum of the deviation amounts between the two surface sections is minimal.

The term “continuous” or “continuously connected” in particular in relation to a surface or a structural component which extends in at least one longitudinal direction, such as a skin, plate or wall, is understood herein to mean that the surface or structural component is uninterrupted.

A “continuous course” of a line or edge or surface means that the surface, viewed along a reference direction, comprises no corners over the entire width running transversely to the reference direction, i.e., has a differentiable progression. A “curved course” of a line or edge or surface means that the surface, viewed along a reference direction, has no corners over the entire width running transversely to the reference direction, i.e., has a differentiable course.

A “uniformly curved course” is understood here to mean a curvature without an inflection point.

The term “position” of a point such as a reference point or of a body is understood here to mean the surface coordinates/spatial coordinates and in particular in the three spatial coordinates of the position of the point, such as the reference point or the body. A position of a body is understood here to mean in particular the position of a center or middle point and in particular a center of gravity of the body.

The term “substantially” in particular with regard to an identical shape of two parts or components is used herein to mean identity with deviations of a single feature or of several features of a maximum of 15% deviation and especially 10% deviation of the parts or components.

### DESCRIPTION OF DRAWINGS

Embodiments of the invention are described below with reference to the accompanying figures. The description of features or components of embodiments according to the invention is to be understood here in such a way that a relevant embodiment according to the invention, unless this is explicitly excluded, can also have at least one feature of another embodiment, in each case as an additional feature of this relevant embodiment or as an alternative feature, replacing another feature of that embodiment in question. The figures show:

FIG. 1 a side view of an embodiment of the preloading device according to the invention, which has a spring device with a meander section,

FIG. 2 a side view of a variant of the embodiment of the preloading device according to the invention according to FIG. 1, which has a spring device with a meander section,

FIG. 3 a side view of a further embodiment of the preloading device according to the invention, which comprises two spring devices,

FIG. 4 a side view of a section of one of the spring devices of the further embodiment of the preloading device of FIG. 3,

FIG. 5 a perspective view of the further embodiment of the preloading device according to the invention shown in FIG. 3,

FIG. 6 a top view of the further embodiment of the preloading device according to the invention shown in FIG. 3,

FIG. 7 a further perspective view of the further embodiment of the preloading device according to the invention shown in FIG. 3,

FIG. 8 a side view of, compared to the embodiments shown in FIGS. 1 and 3, another further embodiment of the preloading device according to the invention,

FIG. 9 a side view of an embodiment of the drive device according to the invention, which comprises a preloading device according to FIG. 3 with two spring devices and an actuator located between the two spring devices,

FIG. 10 a top view of the embodiment of the drive device according to the invention shown in FIG. 9,

FIG. 11 a perspective view of the embodiment shown in FIG. 9 of the drive device according to the invention,

FIG. 12 another perspective view of the embodiment shown in FIG. 9 of the drive device according to the invention.

### DETAILED DESCRIPTION

Embodiments of the prestressing device according to the invention are described in variants and alternative embodiments with features based on the figures. The features by which the further alternative embodiments differ from the variants can, according to the invention, also be present in all of the embodiments described herein, both as an alternative to functionally identical or functionally similar features and as additional features.

The preloading device 10 according to the invention comprises a first end part 11, a second end part 12 and at least one spring device F. The spring device F connects the first end part 11 and the second end part 12 along a spring device reference axis RA. The spring device F provides a spring travel along the spring device reference axis RA. The spring device F is formed from a meander section M1, the longitudinal course of which is defined by a meander center line MM.

According to the invention, a first end part 11 referred to herein is intended to be attached or mounted to a first application component not shown in the figures, and a second end part 12 referred to herein is intended to be attached or mounted to a second application component not shown in the figures. When using the preloading device 10 according to the invention, it can be provided that the first application component is moved relative to the second application component against the spring force of the respective spring device F by an actuator which is located between the end parts 11, 12 and moves the end parts 11, 12 along the spring device reference axis RA relative to each other. In an alternative application of the preloading device 10 according to the invention, it can be provided that the first application component is preloaded relative to the second application component by the respective spring device F.

The first end part 11 comprises a first inner surface 11a, which faces the spring device F or the meander section M1. Likewise, the second end part 12 has a second inner surface 12a, which faces the spring device F or the meander section M1. The first inner surface 11a and the second inner surface 12a are thus oriented in such a way that they face each other. The first inner surface 11 a and second inner surface 12a can thus be used as bearing surfaces of a component to be preloaded by the preloading device 10 and in particular by the spring device F. It can be provided that the component to be prestressed is disposed at the first inner surface 11 a and the second inner surface 12a or one of these inner surfaces directly or through an intermediate component, such as a bearing component or a bearing housing which can be formed of elastic material, is present. The component to be prestressed can be located next to the spring device F along or parallel to, but also transverse to, the spring device reference axis RA.

Such a component can in particular be an actuator and specifically a piezoelectric actuator. The functionality of a piezo actuator, which is installed in the preloading device 10 between the first inner surface 11 a and the second inner surface 12a, is preloaded by the respective spring device F, since this results in that the first end part 11 and the second end part 12 or the first inner surface 11 a and the second inner surface 12a compress the component or actuator on opposite sides thereof.

An embodiment according to the invention of the preloading device 10 according to the invention is shown in FIG. 1. The preloading device 10 comprises the first end part 11, the second end part 12 and a single spring device F. The spring device F connects the first end part 11 and the second end part 12 along the spring device reference axis RA, with providing spring travel along the spring device reference axis RA. A coordinate system with a longitudinal axis X, a vertical axis Y and a transverse axis Z is shown in FIG. 1. The position of the coordinate system in relation to the preloading device 10 can be defined in particular in such a way that the XY-plane, i.e., the plane spanned by the X-axis and the Y-axis, extends along a central plane of the spring device F or is identical to the same and that the X-axis also runs in the direction of the center line of the spring device F.

The first end part 11 comprises a first support part 13 and a first connection part 21. Similarly, the second end part 12 comprises a second support part 14 and a second connection part 22. The first connection part 21 and the second connection part 22 form a connection device 20 with which the spring device F is connected to the first end part 11 with a first end E1 and to the second end part 12 with a second end E2.

For this purpose, the first support part 13 comprises a first end section 15 and a second end section 17, which is situated opposite to the first end section 15, transversely to the spring device reference axis RA. The second end section 17 is connected to the first connection part 21. The first support part 13 and the first connection part 21 can be produced together, in particular as one piece or in one piece, or can be formed as components that are separate from one another. In an analogous manner, the second support part 14 comprises a first end section 16 and a second end section 18, which is located opposite to the first end section 16, transversely to the spring device reference axis RA. The second end section 18 is connected to the second connection part 22. The second support part 14 and the second connection part 22 can be produced together, in particular as one piece or from one piece, or can be formed as components that are separate from one another.

The first connection part 21 comprises a first end section 23 and a second end section 25, which is located along the spring device reference axis RA opposite to the first end section 23 and which is connected to the first end E1 of the spring device F. The second end section 25 and the first end E1 can be produced together, in particular as one piece or from one piece, or can be formed as components separate from one another. In an analogous manner, the second connection part 22 comprises a first end section 24 and a second end section 26, which is located along the spring device reference axis RA opposite to the first end section 24 and which is connected to the second end E2 of the spring device F. The second end section 26 and the second end E2 can be manufactured together in particular as one piece or from one piece or can be formed as separate components from one another.

The first support part 13 and the first connection part 21 are together formed dimensionally stable. The first connection part 21 and the first end E1 of the spring device F are also formed together in a dimensionally stable manner. Likewise, the second support part 14 and the second connection part 22 are formed together in a dimensionally stable manner. The second connection part 22 and the second end E2 of the spring device F are also formed together in a dimensionally stable manner.

The spring device F is formed from at least one meander section M in each embodiment of the preloading device according to the invention. The at least one meander section M extends in a section along the spring device reference axis RA and in a section transversely to the spring device reference axis RA. In each embodiment of the preloading device according to the invention with one or more of the other features of the preloading device otherwise described herein, it can be provided that several meander sections defined herein can directly adjoin one another or can be connected to one another via one or respectively an intermediate part.

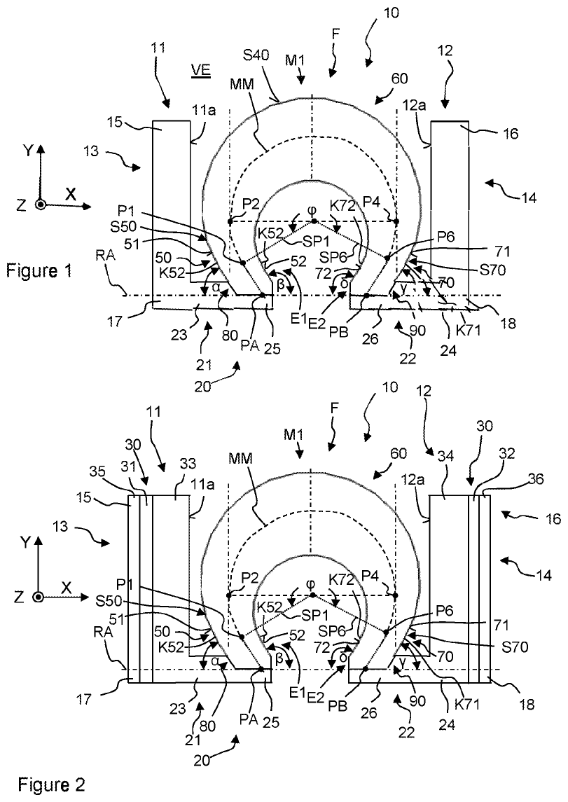

In the embodiments of the preloading device 10 described with reference to FIGS. 1 and 2, the spring device F is formed as a single meander section M, which in its course comprises a meander center line MM and the following sections (A1), (A2), (A3):
(A1) a first transversal section 50, which runs from a first transversal section initial point P1 to a first transversal section final point P2, wherein the first transversal section initial point P1 is identical to the meander section initial point P1 or the first transversal section initial point P1 is disposed by means of an initial section 80 in a distance from the meander section initial point PA, wherein the course of the meander center line in the first transversal section 50, is defined in such a way that, when a line point moves on the meander center line MM from the first transversal section initial point P1 to the first transverse section final point P2, a point resulting from the perpendicular projection of the moved line point onto the spring device reference axis RA approaches the first end part 11,
(A2) a bridging section 60 or connection section, which extends from the first transversal section final point P2 in direction to the second end part 12 to a bridging section end point P4,
(A3) a second transversal section 70, which runs from the bridging section final point P14 to a second transversal section final point P16, which is identical to the meander section final point PB1 or is located at a distance from the meander section final point PB1 by means of an end section 190, wherein the course of the meander center line in the second transversal section 170 is defined in such a way that when a line point moves on the meander center line from the bridging section final point P14 to the second transversal section final point P16, a point, which results from the perpendicular projection of the moved line point onto the spring device reference axis RA1, approximates the first end part 11.

In all embodiments of the preloading device 10, in which the meander section initial point PA is located in a distance from the first transverse section initial point P1, it can be provided in particular that the center line, which runs from the meander section initial point PA to the first transverse section initial point P1, runs transversely to the spring device reference axis RA.

Irrespective of this, in all embodiments of the preloading device 10 in which the meander section final point PB is located in a distance from the second transverse section final point P6, it can be provided in particular that the center line, which runs from the meander section final point PB to the second transverse section final point P6, runs transversely to the spring device reference axis RA.

In particular, embodiments of the preloading device 10 can comprise a first spring device F1, a second spring device F2, a first end part 11 and a second end part 12, wherein the first spring device F1 connects the first end part 11 and the second end part 12 along a first spring device reference axis RA1 and the second spring device F2 connects the first end part 11 with the second end part 12 along a second spring device reference axis RA2,
wherein each spring device F1, F2 comprises a meander section M1, M2, each with two transverse sections 50, 70, wherein the distance to each other, when viewed from a reference line or the spring device reference axis RA, RA1, RA2 of the respective spring device, increases in a section and which are connected with each other by means of a bridging section at a greater distance from the reference line or the spring device reference axis RA, RA1, RA2.

In these embodiments according to the invention, it can be provided in particular that between transversal sections of the same meander sections and/or between transversal sections of different adjacent meander sections, at least in a real part of the movement range or in the entire movement range of the respective spring device, a moving space in direction of the reference line or the spring device reference axis exists.

In the embodiment of the preloading device 10 shown in FIG. 1, the meander center line MM of the meander section M is a circle segment line, wherein the center point of the circle segment is defined by the intersection of the following two lines:
(R1) the perpendicular SP1 to the tangent to the meander center line located in the first transverse section 50 in the first transverse section initial point P1;
(R2) the perpendicular SP6 to the tangent to the meander center line in the second transverse section 70 in the second meander final point P6.

The opening angle, which extends between the two perpendiculars SP1, SP6, is greater than 180 degrees. This can generally amount to 180.5 degrees or a larger value. This opening angle is preferably less than 345 degrees and especially less than 330 degrees.

However, it is also conceivable that the meander center line MM of at least one meander section M comprises a geometry which deviates from a circle segment line and, in particular, comprises an arcuate geometry.

FIG. 2 shows a further embodiment of the preloading device 10 according to the invention, which is a variant of the embodiment of the preloading device 10 shown in FIG. 1.

The embodiment of the preloading device 10 of FIG. 2 according to the invention can comprise all combinations of features of the preloading device 10 described with reference to FIG. 1. In addition, the preloading device 10 in FIG. 2 differs from that in FIG. 1 in that both the first end part 11 and the second end part 12 comprise a decoupling device 30. The decoupling device 30 is designed as a first decoupling layer 31, which is arranged as an intermediate layer in the first end part 11, and as a second decoupling layer 32, which is arranged as an intermediate layer in the second end part 12. In variants of the embodiment in FIG. 2, the preloading device 10 comprises only one decoupling layer, i.e., only the decoupling layer 31 or only the decoupling layer 32.

In particular, the decoupling device can be located between two sections or parts of the respective end parts in order to eliminate transverse forces between these sections or parts. The sections or parts are arranged one behind the other along the respective spring device reference axis.

In the embodiment of the preloading device 10 according to the invention according to FIG. 2, the first end part 11 comprises a first or inner partial section 33, which forms the first inner surface 11 a on the side that faces the respective spring device F. Furthermore, the first end part 11 comprises a second or outer section 35, which is located along the spring device reference axis RA adjacent to the first partial section 33, wherein between the first partial section 33 and the second partial section 35 the first decoupling layer 31 is arranged.

Analogous to this, in the embodiment of the preloading device 10 according to the invention according to FIG. 2, the second end part 12 comprises a first or inside section 34 which forms the second inner surface 12a on the side which faces the respective spring device F. Furthermore, the second end part 12 comprises a second or outer section 36, which is located along the spring device reference axis RA next to the first partial section 34, wherein the second decoupling layer 32 is arranged between the first partial section 34 and the second partial section 36.

The decoupling device 30 serves to reduce or eliminate transverse forces directed transversely to the spring device reference axis RA, which act on the first end part 11 or the second end part 12 or both the first end part 11 and the second end part 12 when the first end part 11 and/or the second end part 12 are/is coupled to components of an application device.

The decoupling layer 31 and/or the decoupling layer 32 can in particular be made of a shear thinning material. The shear thinning material is integrated in the first end part 11 or in the second end part 12 or in both, the first end part 11 and the second end part 12, in such a way that transverse forces which act on the respective first partial section 33, 34 cannot be transferred to the respective second partial section 35, 36 of the same end parts 11, 12. The shear thinning material only transfers forces that run along the spring device reference axis RA from the respective second end part 12 to the respective first end part 11 of the same end part 11, 12.

The decoupling device 30 can also be realized in a different way to eliminate the effect of transverse forces directed transversely to the spring device reference axis RA, e.g., as at least one pivot bearing or tilting or swivel bearing or flexure joint or structural joint.

The features of the preloading device 10 described with reference to FIGS. 1 and 2 can be combined with one or more of the other features otherwise described herein of other embodiments of the preloading device.

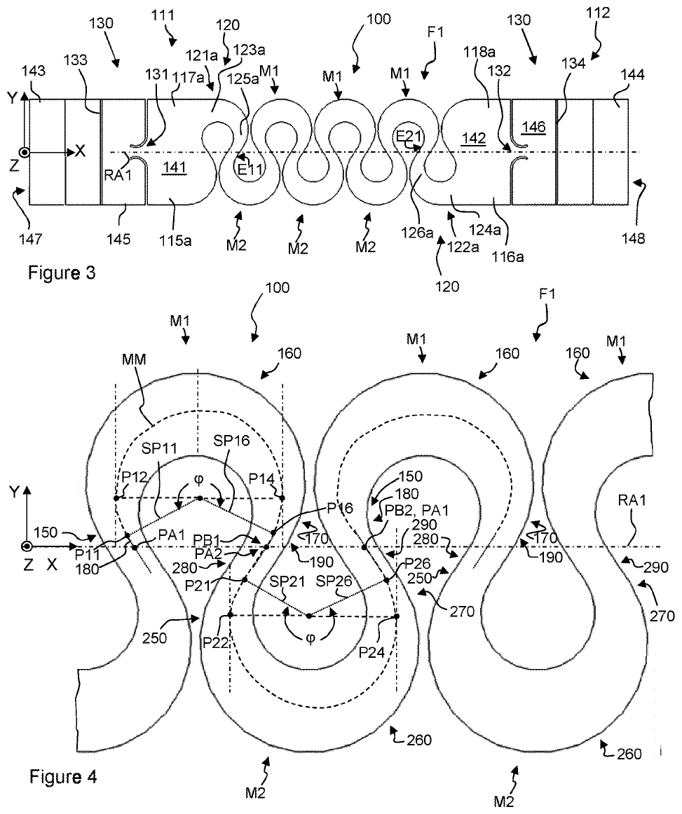

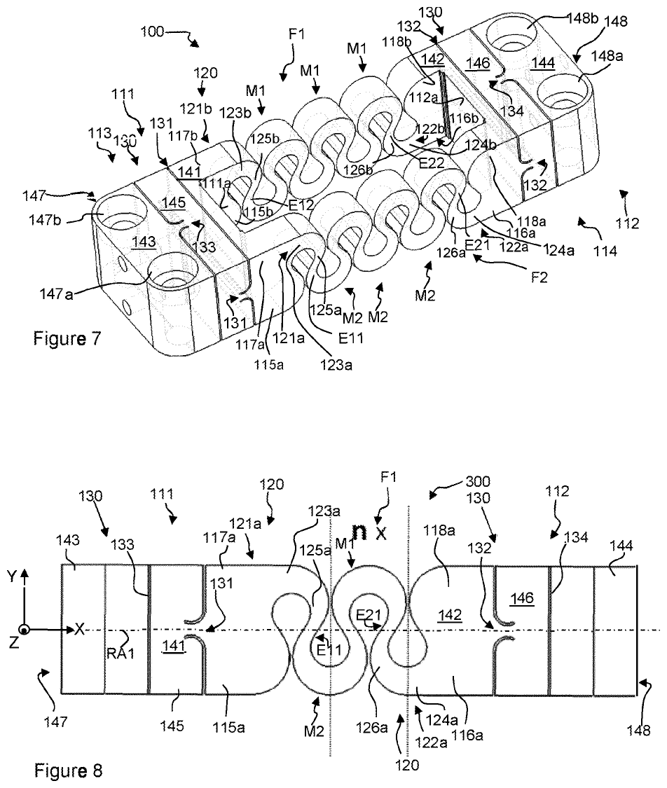

In the following, further embodiments of the preloading device according to the invention are described with reference to FIGS. 3 to 7, which are assigned the reference symbol “100”. Features with the same function are partially assigned the same reference symbols. These embodiments comprise a first end part 111, a second end part 112, a first spring device F1 and a second spring device F2, which cannot be seen in FIG. 1. The first spring device F1, for which a first spring device reference axis RA1 is defined, and the second spring device F2, for which a second spring device reference axis RA2 is defined, can, related to a spring device symmetry axis S which runs along the spring device reference axes RA1, RA2, be arranged axially symmetrically to one another. In particular, it can be provided that the spring device reference axes RA1, RA2 run symmetrically and in particular parallel to the spring device symmetry axis S. The first spring device F1 and the second spring device F2 can in particular be arranged transversely to their spring device reference axes RA1, RA2 and transversely to the spring device symmetry axis S at a distance unequal to zero.

The first end part 111 of the preloading device 100 comprises a first support part 113 and two first connection parts 121a, 121b, which are arranged transversely to the spring device reference axes RA1, RA2 at a distance unequal to zero. Analogously, the second end part 112 of the preloading device 100 comprises a second support part 114 and two second connection parts 122a, 122b, which are arranged transversely to the spring device reference axes RA1, RA2 at a distance unequal to zero. A first end E11 of the first spring device F1 and a first end E12 of the second spring device F2 are each connected to a first connection part 121a, 121b. A second end E21 of the first spring device F1 and a second end E22 of the second spring device F2 are each connected to a second connection part 122a, 122b. The second connection parts 122a, 122b thus form the connection device 120, with which the spring devices F1, F2 are connected to the first end part 111 with a first end E11, E12 and to the second end part 112 with a second end E21, E22.

For this purpose, the first support part 113 comprises two first end sections 115a, 115b and two second end sections 117a, 117b. The first end sections 115a, 115b are located apart from each other in the direction of the distance between the spring device reference axes RA1, RA2. Also, the two second end sections 117a, 117b are located apart from each other in the direction of the distance between the spring device reference axes RA1, RA2. In this case one of the first end sections 115a, 115b is located opposite to a second end section 117a, 117b in a direction that runs transversely to a plane spanned by the mentioned distance and one of the spring device reference axes RA1, RA2. The second end sections 117a, 117b are each connected to a first connection part 121a, 121b. The first support part 113 and the first connection parts 121a, 121b can be produced together, in particular as one piece or in one piece, or can be formed as components that are separate from one another.

In an analogous manner, the second support part 114 comprises two first end sections 116a, 116b and two second end sections 118a, 118b. The first end sections 116a, 116b are located apart from each other in the direction of the distance between the spring device reference axes RA1, RA2. Also, the two second end sections 118a, 118b are located apart from each other in the direction of the distance between the spring device reference axes RA1, RA2. In this case each of the first end sections 116a, 116b is located opposite to a second end section 118a, 118b in a direction that runs transversely to a plane spanned by the mentioned distance and one of the spring device reference axes RA1, RA2. The second end sections 118a, 118b are each connected to a second connection part 122a, 122b. The second support part 114 and the second connection parts 122a, 122b can be produced together, in particular as one piece or from one piece, or can be formed as components that are separate from one another.

Each of the first connecting parts 121a, 121b comprises a first end section 123a or 123b and a second end section 125a or 125b, which are located opposite the respective first end section 123a, 123b and which each are connected with a first end E11, E12 to the respective spring device F1 or F2. The second end section 125a, 125b and the respective first end E11 or E12 can be produced together, in particular as one piece or from one piece, or can be formed as components that are separate from one another.

In an analogous manner, the second connection parts 122a, 122b each comprise a first end section 124a or 124b and a second end section 126a or 126b, which are located opposite the respective first end section 124a, 124b and each are connected with a second end E21, E22 with the respective spring device F1 or F2. In each case a second end section 126a, 126b and the respective second end E21 or E22 can be produced together, in particular as one piece or from one piece, or can be formed as components which are separate from one another.

The first support part 113 and the first connection parts 121a, 121b are formed together in a inherently stable manner. The first connecting parts 121a, 121b and the respective first end E11, E12 of the spring device F1 or F2 are also formed together in an inherently stable manner. Likewise, the second support part 114 and the second connection parts 122a, 122b are formed together in an inherently stable manner. The second connection parts 122, 122b and the respective second end E21, E22 of the spring device F1 or F2 are also formed together in an inherently stable manner.

Each spring device F1, F2 comprises three first meander sections M1 and three second or more meander sections M2. The first meander sections M1 and the second or further meander sections M2 extend in opposite directions to one another. A meandering center line MM can be defined for each of these in its courses. Furthermore, the first meander sections M1 and the second or further meander sections M2 extend along the spring device reference axis RA1 or RA2.

In general, each spring device F1, F2 can comprise a meander section M1, M2 or several meander sections M1, M2. In case that a spring device F1, F2 comprises several meander sections M1, M2, a first meander section M1 and a second meander section M2 or vice versa are arranged one behind the other along the respective spring device reference axis RA1 or RA2.

The meander sections of each spring device F1, F2 comprise a width b, which can be constant or can vary along the respective spring device reference axis RA1 or RA2.

The at least one first meander section M1 and the at least one second meander section M2 each comprise the sections (A1), (A2), (A3), as these are also defined with reference to FIG. 1 For the description of the first meander sections M1 and the second meander sections M2, the same reference symbols are used in relation to the first spring device F1 and the second spring device F2 for features of the same function.

The first meander sections M1 show:
(A1) a first transversal section 150, which runs from a first transversal section initial point P11 to a first transversal section final point P12, wherein the first transversal section initial point P11 is identical to the meander section initial point PA1 or the first transversal section initial point P11 is disposed by means of an initial section 180 in a distance from the meander section initial point PA1, wherein the course of the meander center line in the first transversal section 150 is defined in such a way that, when a line point moves on the meander center line MM from the first transversal section initial point P11 to the first transverse section final point P12, a point resulting from the perpendicular projection of the moved line point onto the spring device reference axis RA1 approaches the first end part 111,
(A2) a bridging section 160, which extends from the first transversal section final point P12 in direction to the second end part 112 to a bridging section final point P14,
(A3) a second transversal section 170, which runs from the bridging section final point P14 to a second transversal section final point P16, which is identical to the meander section final point PB1 or is located at a distance from the meander section final point PB1 by means of an end section 190, wherein the course of the meander center line in the second transversal section 170 is defined in such a way that when a line point moves on the meander center line from the bridging section final point P14 to the second transversal section final point P16, a point, which results from the perpendicular projection of the moved line point onto the spring device reference axis RA1, approximates the first end part 11.

In the first meander sections M1 of the embodiment of the prestressing device 100 shown in FIGS. 3 to 7, the meander center line MM of the meander section M is a circle segment line, the center point of the circle segment being defined by the intersection of the following two lines:
(R1) the perpendicular SP11 to the tangent that abuts the meander centerline in the first transverse section start point P11, wherein the meander centerline is disposed in the first transverse section 150;
(R2) the perpendicular SP16 to the tangent that abuts the meander center line located in in the second meander end point P16, wherein the meander centerline is disposed in the second transverse section 170.

The second meander sections M2 comprise:
(A1) a first transversal section 250, which runs from a first transversal section initial point P21 to a first transversal section final point P22, wherein the first transversal section initial point P21 is identical to the meander section initial point PA2 or the first transversal section initial point P21 is disposed by means of an initial section 280 in a distance from the meander section initial point PA2, wherein the course of the meander center line in the first transversal section 250 is defined in such a way that, when a line point moves on the meander center line MM from the first transversal section initial point P21 to the first transverse section final point P22, a point resulting from the perpendicular projection of the moved line point onto the spring device reference axis RA2 approaches the first end part 111,
(A2) a bridging section 260, which extends from the first transversal section final point P22 in direction to the second end part 112 to a bridging section final point P24,
(A3) a second transversal section 270, which runs from the bridging section final point P24 to a second transversal section final point P26, which is identical to the meander section final point PB2 or is located at a distance from the meander section final point PB2 by means of an end section 290, wherein the course of the meander center line in the second transversal section 270 is defined in such a way that when a line point moves on the meander center line from the bridging section final point P24 to the second transversal section final point P26, a point, which results from the perpendicular projection of the moved line point onto the spring device reference axis RA2, approaches the first end part 111.

In the second meander sections M2 of the embodiment of the preloading device 100 shown in FIGS. 3 to 7, the meander center line MM of the meander section M is a circle segment line, wherein the center point of the circle segment is defined by the intersection of the following two lines:
(R1) the perpendicular SP21 to the tangent to the meander center line in the first transverse section initial point P21, wherein the meander centerline is disposed in the first transversal section 250;
(R2) the perpendicular SP26 to the tangent to the meander center line in the second meander-final point P26, wherein the meander centerline is in the second transversal section 270.

In the embodiment of the preloading device 100 shown in FIGS. 3 to 7, a second meander section M2 with a first transversal section 250 according to the definition (A1) adjoins the second transversal section 170 of each first meander section M1.

The preloading device according to the invention and in particular one of the preloading devices 10 or 100 described herein, i.e. with a first end part 11 or 111, with a second end part 12 or 112 and with at least one spring device F or F1 or F2, which in each case connects the first end part 11 or 111 and the second end part 12 or 112 along a spring device reference axis RA or RA1 or RA2, is generally-formed by at least one spring device F or F1 or F2. The preloading device according to the invention comprises, also independently of the features of the same otherwise described herein, at least one spring device F, F1, F2 with at least one meander section M or M1 or M2, which has an overall elongated shape and forms the shape of a meander loop
(B1) with a first transversal section 50 or 150 or 250,
(B2) with a bridging section 60 or 160 or 260 and
(B3) with a second transversal section 70 or 170 or 270.

The meander section M or M1 or M2 generally has an elongated shape. The first transversal section 50 or 150 or 250 and the second transversal section 70 or 170 or 270 together form the meander section M or M1 or M2 in the form of a meander loop.

It can be provided in particular that the first transversal section 50 or 150 or 250 extends at least in a section transversely to the respective spring device reference axis RA or RA1 or RA2 up to a first transversal section end area and the second transversal section 70 or 170 or 270 at least in a section extends transversely to the respective spring device reference axis RA or RA1 or RA2 to a second transverse sections end area.

The bridging section 60 or 160 or 260 connects the first transversal section 50 or 150 or 250 and the second transversal section 70 or 70 or 270. In particular, it can be provided that a first end of the bridging section 60 or 160 or 260 is connected to the first transversal section end area and a second end of the bridging sections 60 or 160 or 260 is connected to the second transversal section end area. The respective bridging section 60 or 160 or 260 can be arranged in such a way that it is located to the side of the respective spring device reference axis RA or RA1 or RA2.

In this context, a vertical plane VE can be defined for the preloading device, in which the respective spring device reference axis RA or RA1 or RA2 is located and which intersects the respective bridging section 60 or 160 or 260. It can be provided in particular that the respective vertical plane VE intersects the same centrally in its longitudinal course along the respective spring device reference axis RA or RA1 or RA2. For this purpose, it can specifically be provided that the respective vertical plane VE intersects the respective bridging section 60 or 160 or 260 in its longitudinal course along the respective spring device reference axis RA or RA1 or RA2 essentially in the middle and in particular in the middle.

In each of these variants, it can be provided that the first transversal section 50 or 150 or 250 comprises a first, in particular continuously extending, outer surface section S50 with at least one of the following subsections (T11), (T12):
(T11) a first surface section 51 which is oriented towards the first end part 11 or 111 at least in a section,
(T12) a second surface section 53, which is oriented opposite to the first surface section 51 and/or is oriented towards the second end part 12 or 112.

In combination with at least one of the subsections T11, T12 defined above of the first transversal section 50 or 150 or 250 or the first surface section 51 or the second surface section 52 or both surface sections 51, 52 it can be provided that the secondary angle α between the contour line, which results from the intersection of the partial section T11 or the first surface section 51 with the vertical plane VE, and the respective spring device reference axis RA or RA1 or RA2, which opens on the side end part of the first end part 11 or 111, is at least in a section less than 90 degrees. In addition, it can be provided that the secondary angle θ between the contour line, which results from the intersection of the partial section T11 or the second surface section 52 with the vertical plane VE, and the respective spring device reference axis RA or RA1 or RA2, which opens on the side of the second end part 12 or 112, is less than 90 degrees, at least in a section.

In combination with this, but also independently-thereof, the first outer surface section S50 can be designed in such a way that the contour lines K51, K52, which result from the intersection of the first outer surface section S50 with the vertical plane VE, run in a straight line.

In combination with at least one of the previously defined sections T11, T12 of the first transversal section 50 or 150 or 250 or the first surface section 51 or the second surface section 52 or both surface sections 51, 52 or independently of these it can be provided that the second transversal section 70 or 170 or 270 comprises a first, in particular continuously extending outer surface section S70 with at least one of the following sections T21, T22:
T21) a first surface section 71 which is oriented towards the second end part 12 or 112 at least in a section,
(T22) a second surface section 72 which is oriented in the opposite direction to the first surface section 71 and/or is oriented towards the second end part 12 or 112.

In combination with at least one of the subsections (T21), (T22) defined above of the second transversal section 70 or 170 or 270 or the first surface section 71 or the second surface section 72 or both surface sections 71, 72 it can be provided that the secondary angle γ between the contour line, which results from the intersection of the partial section T21 or of the first surface section 71 with the vertical plane VE, and the respective spring device reference axis RA or RA1 or RA2, which opens on the side of the second end part 12 or 112, at least in a section is less than 90 degrees. In addition, it can be provided that the secondary angle δ between the contour line, which results from the intersection of the partial section (T22) or of the second surface section 72 with the vertical plane VE, and the respective spring device reference axis RA or RA1 or RA2, which opens on the side end part of the first end part 11 or 111, is greater than 90 degrees, at least in a section.

In combination with this, but also independently of this, the second outer surface section S70 can be designed in such a way that the contour lines K71, K72, which result from the intersection of the second outer surface section S70 with the vertical plane VE, run in a straight line.

In these embodiments of the preloading device according to the invention, as is described, as an example, with reference to FIG. 3, it can be provided
that the spring device F, F1, F2 comprises at least two meandering sections M1, M2, which each comprise the sections (B1), (B2), (B3),
wherein a second transversal section 70, 170 270 of a first meander section M1, M2 is followed by a first transversal section 50, 150, 250 of a second meander section M1, M2,
wherein the bridging sections 60, 160, 260 of meander sections M1, M2, which are located one behind the other along the spring device reference axis RA, RA1, RA2, are located periodically alternately on different sides of the spring device reference axis RA, RA1, RA2.

Provision can be made in particular that two meander sections M1, M2 following one another along the respective spring device reference axis RA, RA1, RA2 are disposed point-symmetrical to one another. Thereby at least one S-shaped meander is formed.

In the embodiment of the preloading device 100 shown in FIGS. 3 to 7, the first transversal sections 150 of the first meander sections M1 and the first transversal sections 250 of the second meander sections M2 extend each from their respective first transversal section initial point P11 or P21 with respect to the spring device reference axis RA in mutually opposite directions.

In the embodiment shown in FIGS. 3 to 7, the first spring device F1 and the second spring device F2 are realized in a manner identical to one another. In principle, the first spring device F1 and the second spring device F2 can also be implemented in ways that differ from one another.

The first end part 111 comprises a first inner surface 111a, which faces the spring devices F1, F2. Likewise, the second end part 112 comprises a second inner surface 112a, which faces the spring devices F1, F2. The first inner surface 111a and second inner surface 112a are thus oriented in such a way that they face each other. The first inner surface 111a and second inner surface 112a can thus be used as bearing surfaces of a component to be preloaded by the preloading device 100 and in particular by the spring devices F1, F2. It can be provided that the component to be prestressed abut against the first inner surface 111a and the second inner surface 112a or one of these inner surfaces directly or by means of an intermediate component, such as a bearing component or a bearing housing which can be made of elastic material. The component to be prestressed lies between the spring devices F1, F2.

In the embodiment of the preloading device 100 according to the invention according to FIGS. 3 to 7, the preloading device 10, 100 can comprise in particular: a first spring device F1, a second spring device F2, a first end part 11, 111 and a second end part 12, 112, wherein the first spring device F1 connects the first end part 11 and the second end part 12 along a first spring device reference axis RA1, and the second spring device F2 connects the first end part 11, 111 and the second end part 12, 112 along a second spring device reference axis RA2, wherein each spring device F1, F2 comprises in each case a meander section M1, M2 each with two transversal sections 50, 70; 150, 170; 250, 270 which, viewed from a reference line or the spring device reference axis RA, RA1, RA2 of the respective spring device, increase their distance from one another in a section and which, at a greater distance from the reference line or the spring device reference axis RA, RA1, RA2 are connected with each other by means of a bridging section.

In the embodiments of the preloading device 100 according to the invention in FIGS. 3 to 7, both the first end part 111 and the second end part 112 comprise a decoupling device 130, which is integrated in the first end part 111 and in the second end part 112 in each case. In variants of the embodiment of FIGS. 3 to 7, only one of the end parts, i.e., only the first end part 111 or only the second end part 112, comprises a decoupling device 130.

The embodiments of the preloading device 100 of FIGS. 3 to 7 can be realized in such a way that each of the decoupling devices 130 comprises a first pivot bearing with a first axis of rotation and a second pivot bearing with a second axis of rotation, wherein the first axis of rotation and the second axis of rotation run transversely to one another. The first end part 111 comprises a first pivot joint 131 with a first axis of rotation and a second pivot joint 133 with a second axis of rotation, and the second end part 112 comprising a first pivot joint 132 with a first axis of rotation and a second pivot joint 134 with a second axis of rotation. The first pivot joint 131, 132 and the second pivot joint 133, 134 are each realized as a tilting or pivoting bearing in the form of a flexure joint or structural joint.

In the embodiments of the preloading device 100 according to the invention according to FIGS. 3 to 7, the first end part 111 comprises a first or inner section 141 with the end sections 115a, 117a, 115b, 117b, which on the side facing the respective spring device F forms the first inner surface 111a. Furthermore, the first end part 111 comprises a second or outer partial section 143, which is located next to or at a distance to the first partial section 141 along the spring device reference axis RA. An intermediate section 145 is located between the first partial section 141 and the second partial section 143. The first pivot joint 131 is formed or arranged between the first partial section 141 and the intermediate section 145. As a result of this, the first partial section 141 and the intermediate section 145 are supported such that the same can be rotated relative to one another and, in particular, can be tilted or swiveled relative to one another. The second pivot joint 133 is formed or arranged between the intermediate section 145 and the second partial section 143. As a result of this, the first partial section 141 and the intermediate section 145 are supported such that the same can be rotated relative to one another and, in particular, can be tilted or pivoted relative to one another. The axes of rotation of the first pivot joint 131 and of the second pivot joint 133 run vertically to one another.

In the embodiments of the preloading device 100 according to the invention, which are described here with reference to FIGS. 3 to 7, the pivot joints 131, 132 can each be realized as flexure hinges. As a result, the same cause a restoring moment in case of a rotation or tilting of the first partial section 141 relative to the intermediate section 145, or in case of a pivoting or tilting or swiveling of the intermediate section 145 relative to the second partial section 143.

Depending on the application, the pivot joint 131 or the pivot joint 132 can also not be provided, so that the intermediate section 145 is omitted.

Analogously to what is described above, in the embodiments of the preloading device 100 according to the invention, which are described herein with reference to FIGS. 3 to 7, the second end part 112 can comprise a first or inner section 142 with the end sections 116a, 118a, 116b, 118, which forms the second inner surface 112a on the side that faces the respective spring device F. Furthermore, the second end part 112 comprises a second or outer partial section 144 which is located, along the spring device reference axis RA, next to or at a distance from the first partial section 142. An intermediate section 146 is located between the first partial section 142 and the second partial section 144. The first pivot joint 132 is formed or disposed between the first partial section 142 and the intermediate section 146. As a result, thereof, the first partial section 142 and the intermediate section 146 are supported such that the same can be rotated relative to one another and, in particular, can be tilted or swiveled relative to one another. The second pivot joint 134 is formed or disposed between the intermediate section 146 and the second partial section 144. As a result thereof, the first partial section 142 and the intermediate section 146 are supported such that the same can be rotated relative to one another and, in particular, can be tilted or swiveled relative to one another. The axes of rotation of the first pivot joint 132 and the second pivot joint 134 run vertically to one another.

In the embodiment of the preloading device 100 according to the invention according to FIGS. 3 to 7, the pivot joints 133, 134 are each realized as flexure hinge or structural hinge. As a result, in case of a pivoting or tilting or swiveling of the first partial section 142 relative to the intermediate section 146, or in case of a pivoting or tilting or swiveling of the intermediate section 146 relative to the second partial section 144, a restoring torque is caused.

Depending on the application case, the pivot joint 132 or the pivot joint 134 may not be provided, so that the intermediate section 146 is omitted.

According to the invention, the second partial section 143 as part of the first end part 111 is intended to be attached or mounted to a first application component which is not shown in the figures, and the second partial section 144 as part of the second end part 112 is intended to be fastened or mounted on a second application component which is not shown in the figures.

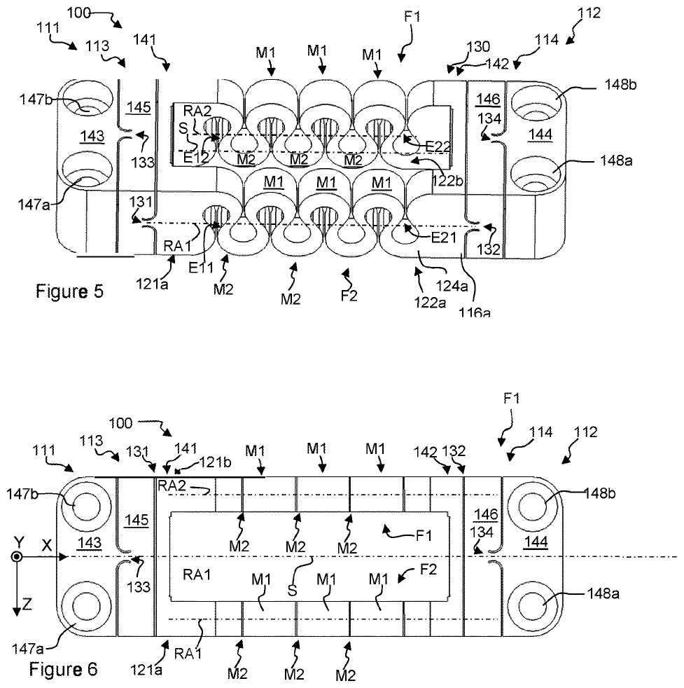

The outer partial section 143 can comprise a mounting device 147 for coupling the outer partial section 143 to a first application component of the application environment or for mounting the outer partial section 143 to a first application component of the application environment. The mounting device 147 can in particular comprise at least one mounting hole or another fastening component. In the representations of FIGS. 5 to 7, the mounting device 147 comprises two mounting holes 147a, 147b.

The outer partial section 144 may include a mounting device 148 for coupling the outer partial section 144 to a second application component of the application environment or for attaching the outer partial section 144 to a second application component of the application environment. The mounting device 148 can in particular comprise at least one mounting hole or another fastening component. In the representations of FIGS. 5 to 7, the mounting device 148 comprises two mounting holes 148a, 148b.

When the preloading device 10 is used according to the invention, it can be provided that the first application component is moved relative to the second application component against the spring force of the respective spring device F1, F2, in that an actuator which is located between the end parts 111, 112 moves the end parts 111, 112 along the spring device reference axes RA1, RA2 relative to each other. In an alternative application of the preloading device 100 according to the invention, it can be provided that the first application component is preloaded by the respective spring device F relative to the second application component.

The features of the preloading device 100 described with reference to FIGS. 3 to 7 can be combined with one or more of other features of other embodiments of the preloading device otherwise described herein.

The embodiment of the preloading device 300 shown in FIG. 8 differs from the preloading device 100 of FIGS. 3 to 7 in that each spring device F1, F2 comprises only a first meander section M1 and a second meander section M2.

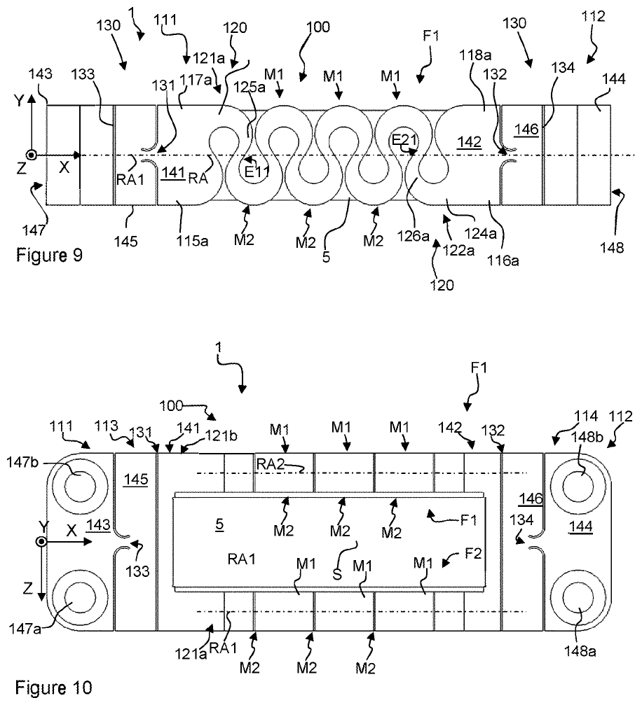

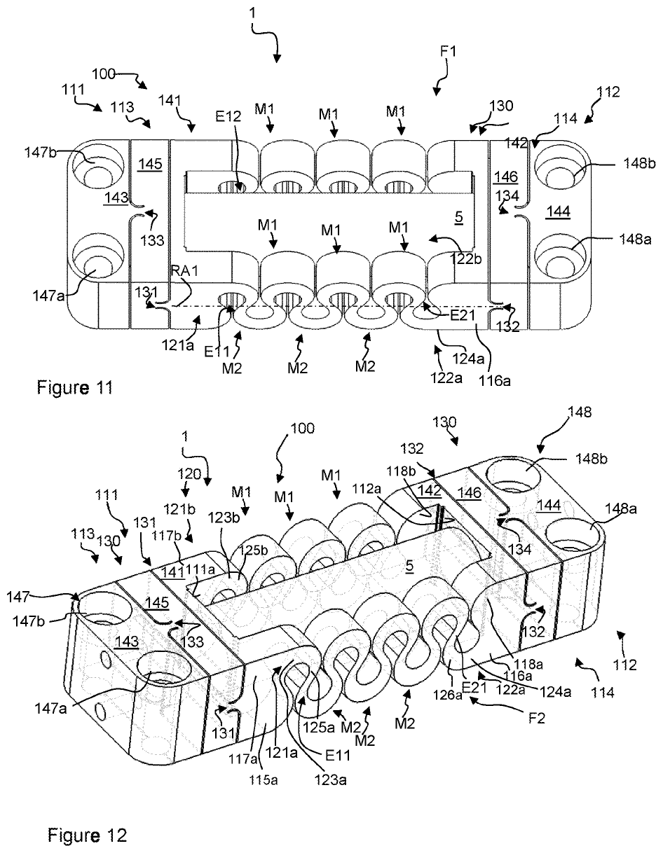

In the FIGS. 9 to 12 an embodiment of the drive device 1 according to the invention is shown.

In general, the drive device 1 comprises a preloading device, which is realized according to an embodiment described herein, and an actuator 5, preferably a piezoelectric actuator. The actuator 5 is disposed between the first end part and the second end part of the preloading device. In this case, the actuator 5 is realized in particular in such a manner that the same, in case of a corresponding electrical actuation, expands or contracts along the spring device reference axis. When an actuator is used in the drive device 1, the same can be realized such that the functionality of the actuator 5 is produced or improved by a lateral prestress that acts on the actuator 5 from opposite sides of the actuator 5 along the spring device reference axis.

The embodiment of the drive device 1 according to the invention shown in FIGS. 9 to 12 comprises the preloading device 100, which is shown in FIGS. 3 to 7 and is described herein with reference to FIGS. 3 to 7. The actuator 5 is disposed between the first end part 111 and the second end part 112 of the preloading device 100.

Alternatively, the drive device 1 can also comprise another preloading device described herein, in particular an embodiment of the preloading device 10, which is described herein with reference to FIGS. 1 and 2, or in particular an embodiment of the preloading device 300, which is described herein with reference to FIG. 8.

### REFERENCE NUMBERS

10 preloading device
11 first end part
11a first inner surface (of the first end part 11)
12 second end part
12a second inner surface (of the second end part 12)
13 first support part (of the first end part 11)
14 second support part (of the second end part 12)
15 first end section (of the first support part 13)
16 first end section (of the second support part 14)
17 second end section (of the first support part 13)
18 second end section (of the second support part 14)
20 connection device
21 first connection part
22 second connection part
23 first end section (of the first connection part 21)
24 first end section (of the second connection part 22)
25 second end section (of the first connection part 21)
26 second end section (of the second connection part 22)
30 decoupling device
31 decoupling layer (of the decoupling device 30)
32 decoupling layer (of the decoupling device 30)
33 first partial section (of the first end part 11)
34 first partial section (of the second end part 12)
35 second partial section (of the first end part 11)
36 second partial section (of the second end part 12)
50 first transversal section (of the meander section M)
60 bridging section (of the meander section M)
70 second transversal section (of the meander section M)
80 initial section (of the first transversal section 50)
90 end section (of the second transversal section 70)
100 preloading device
111 first end part
111a first inner surface (of the first end part 111)
112 second end part
112a second inner surface (of the second end part 112)
113 first support part (of the first end part 111)
114 second support part (of the second end part 112)
115a first end section (of the first support part 113)
115b first end section (of the first support part 113)
116a first end section (of the second support part 114)
116b first end section (of the second support part 114)
117a second end section (of the first support part 113)
117b second end section (of the first support part 113)
118a second end section (of the second support part 114)
118b second end section (of the second support part 114)
120 connection device
121a first connection part (of the first end part 111)
121b first connection part (of the first end part 111)
122a second connection part (of the second end part 112)
122b second connection part (of the second end part 112)
123a first end section (of the first connection part 121a, 121b)
123b first end section (of the first connection part 121a, 121b)
124a first end section (of the second connection part 122a, 122b)
124b first end section (of the second connection part 122a, 122b)
125a second end section (of the first connection part 121a, 121b)
125b second end section (of the first connection part 121a, 121b)
126a second end section (of the second connection part 122a, 122b)
126b second end section (of the second connection part 122a, 122b)
130 decoupling device
131 first pivot joint (of the first end part 111)
132 first pivot joint (of the second end part 112)
133 second pivot joint (of the first end part 111)
134 second pivot joint (of the second end part 112)
141 first partial section (of the first end part 111)
142 first partial section (of the second end part 112)
143 second partial section (of the first end part 111)
144 second partial section (of the second end part 112)
145 intermediate section (of the first end part 111)
146 intermediate section (of the second end part 112)
147 first mounting device (of the first end part 111)
147a mounting hole (of the first end part 111)
147b mounting hole (of the first end part 111)
148 second mounting device (of the second end part 112)
148a mounting hole (of the second end part 112)
148b mounting hole (of the second end part 112)
150 first transversal section (of the first meander section M1)
160 bridging section (of the first meander section M1)
170 second transversal section (of the first meander section M1)
180 initial section (of the first transversal section 150)
190 end section (of the second transversal section 170)
250 first transversal section (of the second meander section M2)
260 bridging section (of the second meander section M2)
270 second transversal section (of the second meander section M2)
280 initial section (of the first transversal section 250)
290 end section (of the second transversal section 250)
300 preloading device
A1 section
A2 section
A3 section
E1 first end of the respective spring device
E2 second end of the respective spring device
E11 first end of the spring device F1
E12 second end of the spring device F1
E21 first end of the spring device F2
E22 second end of the spring device F2
F spring device
F1 spring device
F2 spring device
M meander section
MM meander center line
P1 first transversal section initial point
P2 first transversal section final point
P4 bridging section final point
P6 second transversal section final point
P11 first transversal section initial point
P12 first transversal section final point
P14 bridging section final point
P16 second transversal section final point
P21 first transversal section initial point
P22 first r transversal section final point
P24 bridging section final point
P26 second transversal section final point
PA initial point
PA1 initial point
PA2 initial point
PB final point
PB1 final point
PB2 final point
RA spring device reference axis
RA1 spring device reference axis
RA2 spring device reference axis
S spring devices-Symmetrieachse
SP1 perpendicular to the tangent to the meander center line MM
SP6 perpendicular to the tangent to the meander center line MM
SP11 perpendicular to the tangent to the meander center line MM
SP16 perpendicular to the tangent to the meander center line MM
SP21 perpendicular to the tangent to the meander center line MM
SP26 perpendicular to the tangent to the meander center line MM
X longitudinal axis
Y vertical axis
Z transverse axis

1-16. (canceled)

17. Preloading device, comprising a first spring device, a second spring device, a first end part and a second end part, wherein the first spring device (F1) connects the first end part and the second end part along a first spring device reference axis and the second spring device connects the first end part and the second end part along a second spring device reference axis,
wherein each spring device in each case comprises a meander section each with two transversal sections, the distance between which, when viewed from a reference line or the spring device reference axis of the respective spring device, enlarges in a distance enlargement section, and which are connected with each other in a bridging section that follows the distance enlargement section and is at a greater distance from the reference line or the spring device reference axis as the distance enlargement section.

18. Preloading device according to claim 17, wherein each spring device in each case is formed from at least one meander section which in its course comprises a meander center line, wherein the meander section runs from a meander section initial point to a meander section final point, wherein the meander section initial point and the meander section final point in each case is located on the spring device reference axis and the meander section comprises the following sections (A1), (A2), (A3):
(A1) a first transversal section, which runs from a first transversal section initial point to a first transversal section final point, wherein the first transversal section initial point is identical to the meander section initial point or the first transversal section initial point is disposed by means of an initial section in a distance from the meander section initial point, wherein the course of the meander center line in the first transversal section is defined in such a way that, when a line point moves on the meander center line (MM) from the first transversal section initial point to the first transversal section final point, a point resulting from the perpendicular projection of the moved line point onto the spring device reference axis RA approaches the first end part,
(A2) a bridging section, which extends from the first transversal section final point in direction to the second end part to a bridging section end point,
(A3) a second transversal section, which runs from the bridging section final point to a second transversal section final point, which is identical to the meander section final point or is located at a distance from the meander section final point by means of an end section, wherein the course of the meander center line in the second transversal section is defined in such a way that when a line point moves on the meander center line from the bridging section final point to the second transversal section final point, a point, which results from the perpendicular projection of the moved line point onto the spring device reference axis, approaches the first end part.

19. Preloading device according to claim 18, wherein the distance between the first transversal section final point and the bridging section final point extends parallel to the spring device reference axis.

20. Preloading device according to any one of claim 18, wherein the section of the meander center line at least of one meander section between the first transversal section final point and the bridging section final point comprises one of the following forms:
(C1) a straight course;
(C2) a curved course with a uniform curvature that is concave when viewed from the spring device reference axis.

21. Preloading device according to any one of claim 18, wherein at least one meander section is shaped in such a way that the section of the meander center line between the first transversal section initial point and the transversal section final point is a circle segment line, wherein the center point of the circle segment is defined by the intersection of the following two lines:
(R1) the perpendicular on the tangent to the meander center line in the first transverse section initial point in the first transverse section,
(R2) the perpendicular to the tangent to the meander center line in the second meander final point in the second transverse section,
wherein the opening angle φ, which extends between the two perpendiculars, is greater than 180 degrees and less than 330 degrees.

22. Preloading device according to claim 17, wherein the first spring device and the second spring device each comprise at least two meander sections, wherein each comprise the sections (A1), (A2), (A3), wherein the bridging sections of meander sections in each case of the same spring device, which are located one behind the other along the respective spring device reference axis, are located periodically alternately on different sides of the respective spring device reference axis.

23. Preloading device according to claim 22, wherein the spring device reference axis is a center line of the spring device.

24. Preloading device according to claim 17, wherein each spring device comprises two meander sections, wherein a first meander section comprises the sections (A1), (A2), (A3),
wherein a further meander section is connected to the second transverse section of the first meander section with a first transverse section according to the definition,
wherein the further meander section comprises a bridging section according to the definition, which is connected to the first transversal section of the further meander section,
wherein the further meander section (M2) comprises a second transversal section according to the definition (A3), which is connected to the bridging section of the further meander section,
wherein the bridging section of the first meander section and the bridging section of the further meander section are located on mutually different sides of the spring device reference axis RA.

25. Preloading device according to claim 17, wherein the thickness of at least one meander section increases continuously along the course of the meander center line in an area between the first transversal section initial point and the second transversal section final point, and decreases again after reaching a maximum thickness, wherein the maximum thickness exists in a middle area of the bridging section.

26. Preloading device according to claim 17,
wherein the preloading device comprises at least two meander sections which are located directly adjacent to one another,
wherein one of the meander sections comprises an end section and the adjacent meander section (M1, M2) comprises an initial section, wherein the initial section is directly directly connected to the end section.

27. Preloading device according to claim 26, wherein the initial section, which is directly connected to the end section, is disposed point-symmetrical to the end section.

28. Preloading device according to claim 17, wherein the first spring device reference axis of the first spring device and the second spring device reference axis of the second spring device are disposed axially symmetrically to each other relative to a spring device symmetry axis.

29. Preloading device according to claim 28, wherein the first spring device reference axis of the first spring device and the second spring device reference axis of the second spring device run parallel to one another.

30. Drive device, comprising:
a preloading device with a first spring device, a second spring device, a first end part and a second end part, wherein the first spring device connects the first end part and the second end part along a first spring device reference axis and the second spring device connects the first end part and the second end part along a second spring device reference axis, wherein each spring device in each case comprises a meander section each with two transversal sections, the distance between which, when viewed from a reference line or the spring device reference axis of the respective spring device, enlarges in a distance enlargement section, and which are connected with each other in a bridging section that follows the distance enlargement section and is at a greater distance from the reference line or the spring device reference axis as the distance enlargement section,
an actuator which is disposed between the first end part and the second end part. and expands or contracts along the spring device reference axis upon actuation.

31. Drive device according to claim 30,
wherein each spring device in each case is formed from at least one meander section which in its course comprises a meander center line, wherein the meander section runs from a meander section initial point to a meander section final point, wherein the meander section initial point and the meander section final point in each case is located on the spring device reference axis and the meander section comprises the following sections (A1), (A2), (A3):
(A1) a first transversal section, which runs from a first transversal section initial point to a first transversal section final point, wherein the first transversal section initial point is identical to the meander section initial point or the first transversal section initial point is disposed by means of an initial section in a distance from the meander section initial point, wherein the course of the meander center line in the first transversal section is defined in such a way that, when a line point moves on the meander center line from the first transversal section initial point to the first transversal section final point, a point resulting from the perpendicular projection of the moved line point onto the spring device reference axis RA approaches the first end part,
(A2) a bridging section, which extends from the first transversal section final point in direction to the second end part to a bridging section end point,
(A3) a second transversal section, which runs from the bridging section final point to a second transversal section final point, which is identical to the meander section final point or is located at a distance from the meander section final point by means of an end section, wherein the course of the meander center line in the second transversal section is defined in such a way that when a line point moves on the meander center line from the bridging section final point to the second transversal section final point, a point, which results from the perpendicular projection of the moved line point onto the spring device reference axis, approaches the first end part.

32. Preloading device with a first end part, with a second end part and with at least one spring device, which connects the first end part to the second end part along a spring device reference axis,
wherein at least one spring device in each case comprises at least one meander section (M1, M2) each with two transversal sections, the distance of which, when viewed from a reference line or the spring device reference axis of the respective spring device, increases from one another in a section and which are connected to one another with a bridging section at a greater distance from the reference line or the spring device reference axis,
wherein the first end part or the second end part or both the first end part and the second end part comprise a decoupling device for elimination of the effect of transverse forces which are directed transversely to the spring device reference axis,
wherein the decoupling device forms one of the following feature groups (U), (V) or both of the following feature groups (U), (V):
(U) the decoupling device has a first pivot bearing with a first axis of rotation and a second pivot bearing with a second axis of rotation, wherein the first axis of rotation and the second axis of rotation run transversely to one another,
(V) the decoupling device comprises at least one flexure hinge or structural hinge.

33. Preloading device according to claim 32, wherein the at least one spring device is formed from at least two meander sections, each of which form the shape of a meander loop with
(B1) a first transversal section,
(B2) a bridging section,
(B3) a second transversal section,
wherein the bridging section connects the first transversal section to the second transversal section, wherein a vertical plane intersects the bridging section at least in a section,
wherein the first transversal section comprises a first outer surface section (S50) with at least one first surface section, which is oriented towards the first end part at least in a section, and a second surface section, which is oriented opposite to the first surface section, wherein that secondary angle α between the contour line, which results from the intersection of the first surface section with the vertical plane, and the respective spring device reference axis, which opens on the side end of the first end part, is at least partially less than 90 degrees,
wherein the second transversal section comprises a second outer surface section with at least one first surface section which is oriented towards the second end part at least in a section, and a second surface section, which is oriented opposite to the first surface section, wherein that secondary angle γ between the contour line, which results from the intersection of the first surface section with the vertical plane, and the respective spring device reference axis, which opens on the side of the second end part, is less than 90 degrees, at least in a section,
wherein a first transversal section of a second meander section is connected to a second transversal section of a first meander section,
wherein the bridging sections of meander sections, which are located one behind the other along the spring device reference axis, are located periodically and alternating on different sides of the spring device reference axis.

34. Drive device, comprising:
a preloading device and an actuator which is disposed between the first end part and the second end part. and expands or contracts along the spring device reference axis upon actuation,
wherein the preloading device comprises a first end part, a second end part and at least one spring device, which connects the first end part to the second end part along a spring device reference axis,
wherein at least one spring device in each case comprises at least one meander section each with two transversal sections, the distance of which, when viewed from a reference line or the spring device reference axis of the respective spring device, increases from one another in a section and which are connected to one another with a bridging section at a greater distance from the reference line or the spring device reference axis,
wherein the first end part or the second end part or both the first end part and the second end part comprise a decoupling device for elimination of the effect of transverse forces which are directed transversely to the spring device reference axis,
wherein the decoupling device forms one of the following feature groups (U), (V) or both of the following feature groups (U), (V):
(U) the decoupling device has a first pivot bearing with a first axis of rotation and a second pivot bearing with a second axis of rotation, wherein the first axis of rotation and the second axis of rotation run transversely to one another,
(V) the decoupling device comprises at least one flexure hinge or structural hinge.

35. Drive device according to claim 34, wherein the at least one spring device is formed from at least two meander sections, each of which form the shape of a meander loop with
(B1) a first transversal section,
(B2) a bridging section,
(B3) a second transversal section,
wherein the bridging section connects the first transversal section to the second transversal section, wherein a vertical plane VE intersects the bridging section at least in a section,
wherein the first transversal section comprises a first outer surface section with at least one first surface section, which is oriented towards the first end part at least in a section, and a second surface section, which is oriented opposite to the first surface section, wherein that secondary angle α between the contour line, which results from the intersection of the first surface section with the vertical plane, and the respective spring device reference axis, which opens on the side end of the first end part, is at least partially less than 90 degrees,
wherein the second transversal section comprises a second outer surface section with at least one first surface section which is oriented towards the second end part at least in a section, and a second surface section, which is oriented opposite to the first surface section, wherein that secondary angle γ between the contour line, which results from the intersection of the first surface section with the vertical plane VE, and the respective spring device reference axis, which opens on the side of the second end part, is less than 90 degrees, at least in a section,
wherein a first transversal section of a second meander section is connected to a second transversal section of a first meander section,
wherein the bridging sections of meander sections, which are located one behind the other along the spring device reference axis, are located periodically and alternating on different sides of the spring device reference axis.
